(19) United States
(12) Patent Application Publication
(10) Pub. No.: US 2023/0398625 A1
(43) Pub. Date: Dec. 14, 2023

(54) APPARATUS FOR MANUFACTURING DISPLAY APPARATUS AND METHOD OF MANUFACTURING THE DISPLAY APPARATUS

(71) Applicant: SAMSUNG DISPLAY CO., LTD., Yongin-si (KR)

(72) Inventors: Yonghyun KIM, Yongin-si (KR); Seungho MYOUNG, Yongin-si (KR); Taehun KIM, Yongin-si (KR); Heungyeol NA, Yongin-si (KR)

(21) Appl. No.: 18/113,905

(22) Filed: Feb. 24, 2023

(30) Foreign Application Priority Data
Jun. 13, 2022 (KR) 10-2022-0071726

(51) Int. Cl. B23K 26/03; B23K 26/08; B23K 26/12; B23K 26/035; B23K 26/14

(52) U.S. Cl. CPC B23K 26/032; B23K 26/083; B23K 26/127; B23K 26/035; B23K 26/1436

(57) ABSTRACT

An apparatus for manufacturing a display apparatus includes a chamber in which a loading area is defined, a stage unit disposed in the loading area, where the stage unit fixes a fixing surface of a target, an optical unit disposed outside the chamber, where the optical unit processes a processing surface of the target. The optical unit includes a laser radiating unit which radiates a laser toward the processing surface of the target and a laser moving unit which moves the laser radiating unit along a processing path in a plan view.

This application claims priority to Korean Patent Application No. 10-2022-0071726, filed on Jun. 13, 2022, and all the benefits accruing therefrom under 35 U.S.C. § 119, the content of which in its entirety is herein incorporated by reference.

### BACKGROUND

### 1. Field

One or more embodiments relate to an apparatus, and more particularly, to an apparatus for manufacturing a display apparatus.

### 2. Description of the Related Art

Electronic devices based on mobility (or mobile electronic devices), in addition to small electronic devices, such as mobile phones, tablet personal computers (PC), are widely used in various fields.

Such a mobile electronic device typically includes a display apparatus that provides visual information, such as an image or a video, to a user to support various functions. Recently, as the size of other components for driving a display apparatus has been reduced, the proportion of the display apparatus in an electronic device has gradually increased, and a display apparatus having a structure that may be bent to have a certain angle with respect to a flat state of the display apparatus has been developed.

### SUMMARY

One or more embodiments include an apparatus for manufacturing a display apparatus and a method of manufacturing the display apparatus.

According to one or more embodiments, an apparatus for manufacturing a display apparatus includes a chamber in which a loading area is defined, a stage unit disposed in the loading area, where the stage unit fixes a fixing surface of a target, an optical unit disposed outside the chamber, wherein the optical unit processes a processing surface of the target, where the optical unit includes a laser radiating unit which radiates a laser toward the processing surface of the target and a laser moving unit which moves the laser radiating unit along a processing path in a plan view.

In an embodiment, the apparatus may further include a target moving unit disposed in the loading area, where the target moving unit moves the stage unit, to which the target is fixed, to a processing position.

In an embodiment, the target moving unit may include a target rotationally-moving unit which rotates the stage unit around a first axis.

In an embodiment, the stage unit may fix the fixing surface of the target in a state in which the processing surface of the target faces a direction in which the laser is directed.

In an embodiment, the target rotationally-moving unit may rotate the stage unit in a way such that the processing surface of the target fixed to the stage unit faces a direction opposite to the direction in which the laser is directed.

In an embodiment, the target moving unit may further include a target vertically-moving unit which moves the stage unit in a direction opposite to a direction in which the laser is directed.

In an embodiment, the apparatus may further include a pressure adjusting unit which adjusts a pressure of the loading area.

In an embodiment, the apparatus may further include a window disposed on one side of the chamber, which is between the laser radiating unit and the stage unit, where the window may include a transparent material to allow the laser to pass through.

In an embodiment, the optical unit may further include a laser aligning unit which aligns the laser radiating unit to an alignment position.

In an embodiment, the laser moving unit may include an air-bearing.

According to one or more embodiments, a method of manufacturing a display apparatus includes performing a stage unit arrangement operation by arranging a stage unit to a loading area inside a chamber, performing a target fixing operation by fixing a fixing surface of a target to the stage unit, and performing a processing operation by processing a processing surface of the target, where the performing the processing operation includes performing a laser radiating operation by radiating a laser from a laser radiating unit disposed outside the chamber toward the processing surface of the target, and performing a laser moving operation by moving the laser radiating unit along a processing path in a plan view.

In an embodiment, the method may further include performing a target moving operation by moving the stage unit, to which the target is fixed, to a processing position.

In an embodiment, the performing the target moving operation may include performing a target rotationally-moving operation by rotating the stage unit around a first axis.

In an embodiment, the performing the target fixing operation may include fixing the fixing surface of the target to the stage unit in a state in which the processing surface of the target faces a direction in which the laser is directed.

In an embodiment, the performing the target rotationally-moving operation may include rotating the stage unit in a way such that the processing surface of the target fixed to the stage unit faces a direction opposite to the direction in which the laser is directed.

In an embodiment, the performing the target moving operation may further include performing a target vertically-moving operation by moving the stage unit in a direction opposite to a direction in which the laser is directed.

In an embodiment, the method may further include performing a pressure adjusting operation by adjusting a pressure of the loading area.

In an embodiment, the performing the laser radiating operation may include radiating the laser from the laser radiating unit in a way such that the laser reaches the processing surface of the target through a window disposed on one side of the chamber.

In an embodiment, the performing the processing operation may further include performing a laser aligning operation by aligning the laser radiating unit to an alignment position.

In an embodiment, the performing the laser moving operation may include moving the laser radiating unit along an air-bearing.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view schematically illustrating an apparatus for manufacturing a display apparatus, according to an embodiment;

FIGS. 2A to 2E are cross-sectional views taken along line I-I′ of FIG. 1, showing an operation in which an apparatus for manufacturing a display apparatus loads and processes a target, according to an embodiment;

FIG. 3 is a plan view schematically illustrating a display apparatus manufactured by a method of manufacturing a display apparatus, according to an embodiment;

FIG. 4 is a cross-sectional view schematically illustrating a display apparatus manufactured by a method of manufacturing a display apparatus, according to an embodiment; and

FIG. 5 is an equivalent circuit diagram of a pixel according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below”.

It will be understood that when a layer, region, or component is referred to as being formed on another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

The x-axis, the y-axis, and the z-axis are not limited to three axes on the orthogonal coordinates system, and may be interpreted in a broad sense including the same. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

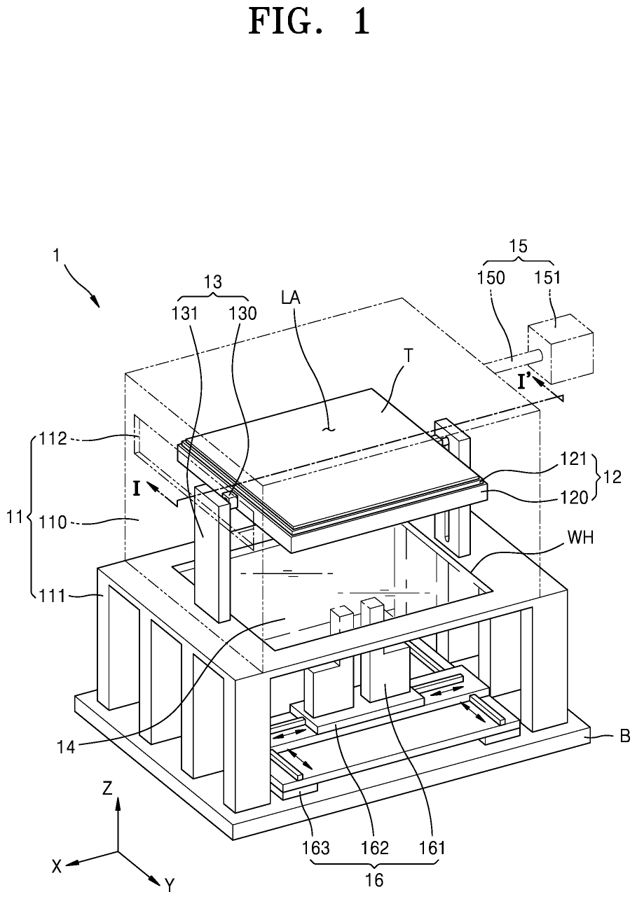

FIG. 1 is a perspective view schematically illustrating an apparatus 1 for manufacturing a display apparatus, according to an embodiment.

Referring to FIG. 1, an embodiment of the apparatus 1 for manufacturing a display apparatus may load a target T therein and process the loaded target T. The apparatus 1 for manufacturing a display apparatus may include a chamber 11, a stage unit 12, a target moving unit 13, a window 14, a pressure adjusting unit 15, and an optical unit 16.

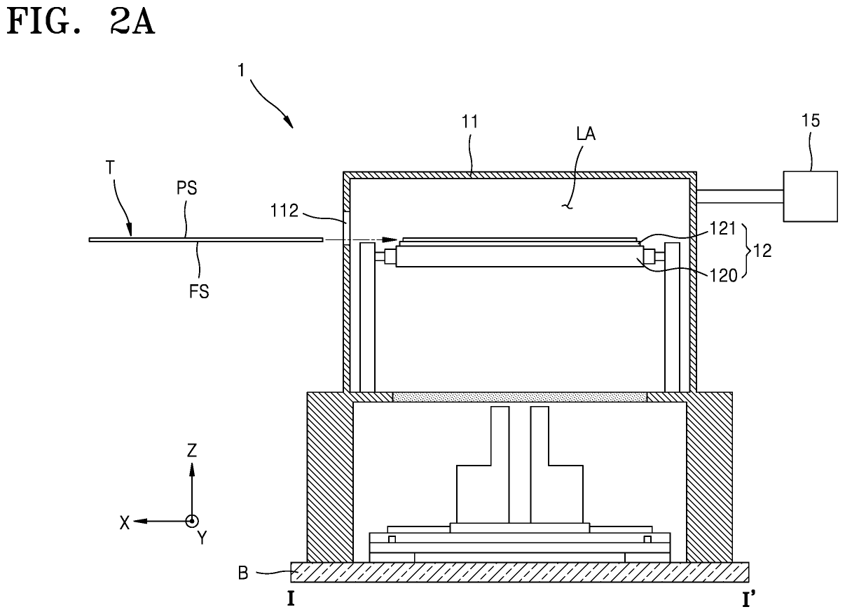

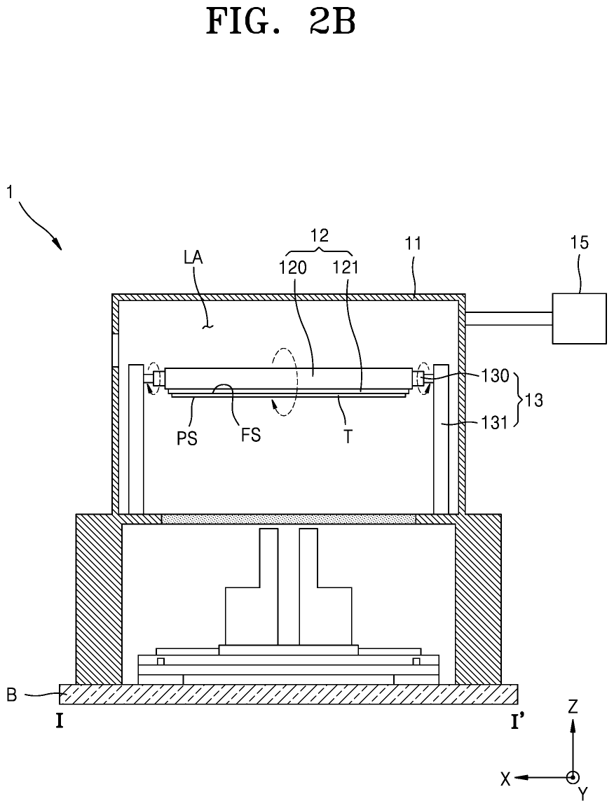

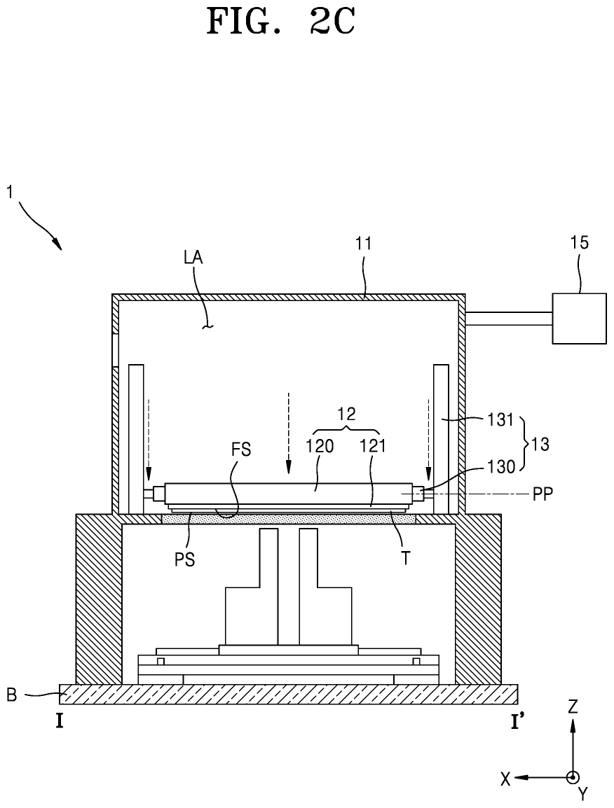

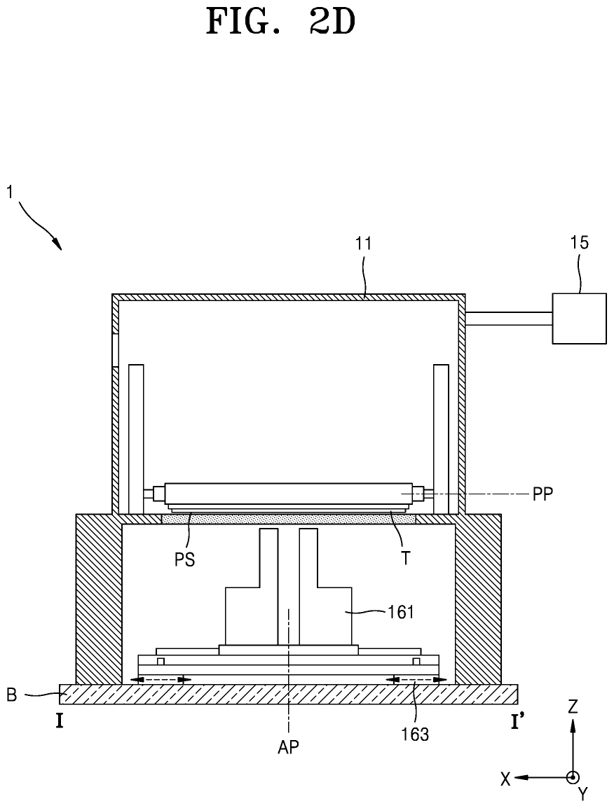

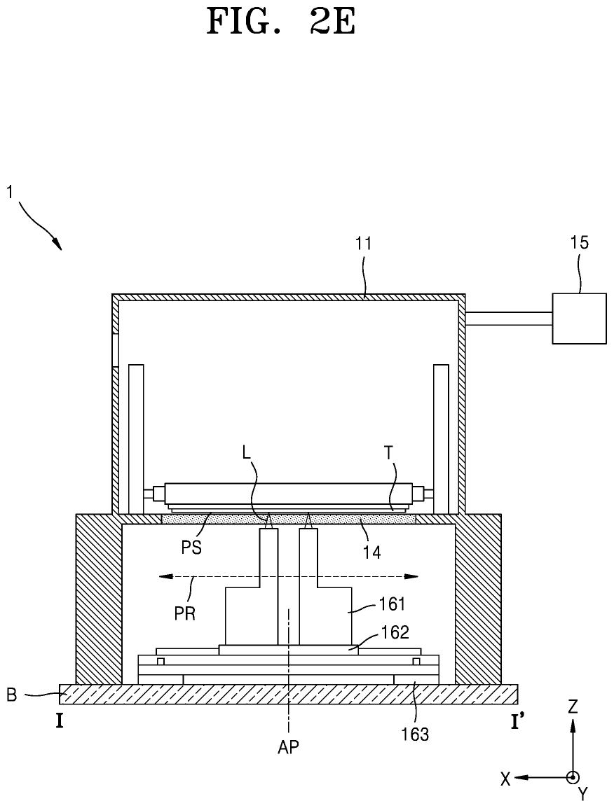

The target T may include a processing surface PS (refer to FIG. 2A) and a fixing surface FS (refer to FIG. 2A). The processing surface PS may be a surface to be processed by the optical unit 16, and the fixing surface FS may be a surface to be fixed to the stage unit 12 to be described below. The target T may have a plate shape. In an embodiment, for example, as shown in FIG. 1, the target T may have a quadrangular plate shape. However, this is only an example, and the shape of the target T may vary depending on the use and processing purpose of the target T.

The chamber 11 may include a chamber body 110, a chamber support 111 and a target slot 112, and a loading area LA, and a window hole WH may be defined in the chamber 11.

The chamber body 110 may form the exterior of the chamber 11. In an embodiment, for example, the chamber body 110 may have a hexahedral shape as shown in FIG. 1. However, this is only an example, and the shape of the chamber body 110 is not limited thereto. The shape of the chamber body 110 may vary depending on the shape or arrangement of components therein and the optical unit 16.

The loading area LA may be defined inside the chamber body 110, and may be an area in which the target T is loaded. Various components for loading the target T as well as the target T may be arranged in the loading area LA. In an embodiment, for example, the stage unit 12 and the target moving unit 13 may be arranged in the loading area LA. Although FIG. 1 illustrates an embodiment where the loading area LA has a hexahedral shape, this is only an example, and the shape of the loading area LA may vary depending on the shape or arrangement of components therein and the optical unit 16, similarly to the chamber body 110.

The chamber support 111 may be disposed on a base B and support the chamber body 110. The chamber support 111 may be arranged to secure a space in which the optical unit 16 is arranged between the base B and the chamber body 110. In an embodiment, for example, the chamber support 111 may have a shape of a plurality of pillars. In such an embodiment, the optical unit 16 may be arranged in a space formed between the plurality of pillars. Although FIG. 1 illustrates an embodiment where the chamber support 111 is in the form of eight quadrangular pillars, this is only an example, and the number and form of the chamber support 111 is not limited thereto.

The target slot 112 may be opened and closed such that the target T may be inserted. That is, the target slot 112 may be opened in an operation of inserting the target T, and may be closed when the target T is completely loaded. When the target slot 112 is closed, the loading area LA may be sealed. In an embodiment, while the pressure adjusting unit 15 to be described below adjusts the pressure of the loading area LA, the pressure adjusting unit 15 may prevent external air from flowing into the loading area LA or air in the loading area LA from being discharged to the outside.

The target slot 112 may have a shape corresponding to the target T such that the target T may be inserted. In an embodiment, for example, as shown in FIG. 1, the target slot 112 may have a quadrangular shape having a long length in a horizontal direction (e.g., Y-axis direction). In such an embodiment, the target T having a plate shape may be efficiently inserted into the loading area LA through the target slot 112. However, this is only an example, and the shape of the target slot 112 may vary depending on the shape of the target T and an insertion method of the target T.

The window hole WH may be a space in which the window 14 to be described below is arranged. The window hole WH may be defined or formed through an upper surface of the chamber support 111 or a lower surface (e.g., a surface facing a −Z-axis direction) of the chamber body 110. That is, the window hole WH and the loading area LA may communicate with each other. In an embodiment, for example, as shown in FIG. 1, the window hole WH may have a quadrangular shape. However, this is only an embodiment, and the shape of the window hole WH is not limited thereto.

The stage unit 12 may be arranged in the loading area LA, and may fix (or be fixed to) the fixing surface FS of the target T. The stage unit 12 may include a stage body 120 and a chuck plate 121.

The stage body 120 may support the chuck plate 121. That is, the chuck plate 121 may be fixed to the stage body 120. The stage body 120 may be connected to the target moving unit 13, and may be moved by the target moving unit 13. As the stage body 120 is moved, the chuck plate 121 and the target T may also be moved along a movement path of the stage body 120.

The chuck plate 121 may be in contact with the fixing surface FS of the target T to fix the target T. The chuck plate 121 may be in the form of an electrostatic chuck, and in an embodiment, the chuck plate 121 may be an electrostatic charge (ESC)-type chuck. In such an embodiment, in a state in which the target T is fixed to the stage unit 12, the fixing surface FS of the target T may be in contact with the chuck plate 121, and the processing surface PS of the target T may be exposed in the loading area LA.

The target moving unit 13 may be arranged in the loading area LA, and may move the stage unit 12, to which the target T is fixed, to a processing position PP (refer to FIG. 2C). The target moving unit 13 may include a target rotationally-moving unit 130 and a target vertically-moving unit 131.

The target rotationally-moving unit 130 may rotate the stage unit 12 around a first axis (e.g., X-axis). That is, the target rotationally-moving unit 130 may rotate the stage unit 12 around a horizontal axis.

The target vertically-moving unit 131 may move the stage unit 12 in a direction (e.g., +Z-axis direction) in which a laser is directed and a direction (e.g., −Z-axis direction) opposite to the direction in which a laser is directed. That is, the target vertically-moving unit 131 may move the stage unit 12 in a vertical direction.

In an embodiment, the target rotationally-moving unit 130 may be connected to the stage body 120 and the target vertically-moving unit 131. In such an embodiment, the target rotationally-moving unit 130 may rotationally move the stage body 120 around the first axis (e.g., X axis) with respect to the target vertically-moving unit 131. The target vertically-moving unit 131 may be connected to the target rotationally-moving unit 130 and the chamber 11. In such an embodiment, the target vertically-moving unit 131 may move the target rotationally-moving unit 130 in a vertical direction (e.g., Z-axis direction) with respect to the chamber 11. Accordingly, the target moving unit 13 may vertically or rotationally move the target T fixed to the stage unit 12 with respect to the base B.

The window 14 may be arranged on one side of the chamber 11, which is between a laser radiating unit 161 and the stage unit 12, and may include a transparent material to allow a laser to pass therethrough. The window 14 may be accommodated in the window hole WH, and may allow a laser radiated by the laser radiating unit 161 to pass through the loading area LA. The window 14 may have a shape corresponding to the window hole WH. In an embodiment, for example, where the shape of the window hole WH is quadrangular as shown in FIG. 1, the shape of the window 14 may also be quadrangular.

The pressure adjusting unit 15 may adjust the pressure of the loading area LA. In a state in which the target slot 112 is closed, the pressure adjusting unit 15 may adjust the pressure of the loading area LA such that the loading area LA is in a vacuum state. The pressure adjusting unit 15 may include a connection pipe 150 and a vacuum pump 151. One side of the connection pipe 150 may be fixed to the chamber body 110, and may communicate with the loading area LA and the vacuum pump 151. The vacuum pump 151 may form a negative pressure in the loading area LA through the connection pipe 150.

The optical unit 16 may be arranged outside the chamber 11 and process the processing surface PS of the target T. The optical unit 16 may be arranged outside the chamber body 110 instead of being arranged in the loading area LA. In an embodiment, for example, the optical unit 16 may be arranged in a space between a plurality of chamber supports 111. The optical unit 16 may include the laser radiating unit 161, a laser moving unit 162, and a laser aligning unit 163.

The laser radiating unit 161 may radiate a laser toward the processing surface PS of the target T in a state in which the stage unit 12 is positioned at the processing position PP. The laser radiating unit 161 may be below the stage unit 12, and a laser radiated by the laser radiating unit 161 may reach the processing surface PS of the target T through the window 14. In an embodiment, the laser radiating unit 161 may be provided in plural. In an embodiment, for example, as shown in FIG. 1, two laser radiating units 161 may be provided. The number of the laser radiating units 161 may be determined according to the use and processing purpose of the target T.

In a plan view, the laser moving unit 162 may move the laser radiating unit 161 along a processing path PR (refer to FIG. 2E) (e.g., the X-axis and/or Y-axis direction) with respect to the base B. That is, while the laser radiating unit 161 is moved along the processing path PR by the laser moving unit 162, the laser radiating unit 161 may process the processing surface PS of the target T by radiating a laser toward the processing surface PS of the target T.

The laser aligning unit 163 may align the laser radiating unit 161 to an alignment position AP (refer to FIG. 2D) before the laser radiating unit 161 radiates a laser. In an embodiment, the laser aligning unit 163 may be provided in plural, and the plurality of laser aligning units 163 may be arranged to be spaced apart from each other in a horizontal direction. Each of the plurality of laser aligning units 163 may move independently from each other in a horizontal direction (e.g., the X-axis and/or Y-axis direction). As the plurality of laser aligning units 163 move in the horizontal direction (e.g., the X-axis and/or Y-axis direction), the laser radiating unit 161 may be pre-aligned to the alignment position AP before a laser is radiated.

FIGS. 2A to 2E cross-sectional views taken along line I-I′ of FIG. 1, showing an operation in which the apparatus 1 for manufacturing a display apparatus loads and process the target T, according to an embodiment.

Referring to FIG. 2A, the target T may be fixed to the stage unit 12 after being inserted into the chamber 11, while the target slot 112 is in an open state.

The target T may be inserted into the loading area LA in a state in which the processing surface PS faces a direction (e.g., +Z-axis direction) in which a laser is directed and the fixing surface FS faces a direction (e.g., −Z-axis direction) opposite to the direction in which a laser is directed, and the fixing surface FS of the target T may be fixed to the stage unit 12. At this time, the fixing surface FS of the target T may be in contact with the chuck plate 121 supported by the stage body 120. When the fixing surface FS of the target T is fixed to the stage unit 12, the target slot 112 may be switched from an open state to a closed state.

Referring to FIGS. 2B and 2C, the target moving unit 13 may move the stage unit 12, to which the target T is fixed, to the processing position PP.

In an embodiment, referring to FIG. 2B, the target rotationally-moving unit 130 may rotate the stage body 120 around a first axis (e.g., X-axis) with respect to the base B. In such an operation, the chuck plate 121 supported by the stage body 120 may also be rotated around the first axis (e.g., X-axis). In a state in which the fixing surface FS of the target T is fixed to the chuck plate 121, the target rotationally-moving unit 130 may rotate the target T such that the processing surface PS of the target T faces a direction (e.g., −Z-axis direction) opposite to a direction in which a laser is directed. That is, the rotation radius of the target rotationally-moving unit 130 may be 180 degrees. The direction (e.g., −Z-axis direction) opposite to the direction in which a laser is directed may be a direction in which gravity acts. Accordingly, a foreign material generated in an operation of processing the processing surface PS of the target T to be described with respect to FIG. 2E may fall in a lower direction (e.g., −Z-axis direction) of the loading area LA instead of the processing surface PS of the target T.

Referring to FIG. 2C, the target vertically-moving unit 131 may move the target rotationally-moving unit 130 in the direction (e.g., −Z-axis direction), which is opposite to the direction in which a laser is directed, with respect to the base B. In such an operation, the stage unit 12 connected to the target rotationally-moving unit 130 may move to the processing position PP. When the stage unit 12 is at the processing position PP, similar to FIG. 2B, in a state in which the fixing surface FS of the target T is fixed to the chuck plate 121 supported by the stage body 120, the processing surface PS of the target T may face the direction (e.g., −Z-axis direction) opposite to the direction in which a laser is directed.

Referring to FIG. 2D, when the stage unit 12 is at the processing position PP, the laser aligning unit 163 may align the laser radiating unit 161 at the alignment position AP. The laser aligning unit 163 may move in a horizontal direction (e.g., the X-axis and/or Y-axis direction) with respect to the base B. In a state in which the laser aligning unit 163 aligns the laser radiating unit 161 at the alignment position AP, the laser radiating unit 161 and the processing surface PS of the target T may face each other with a window therebetween.

Referring to FIG. 2E, in a state in which the laser radiating unit 161 is aligned at the alignment position AP, the laser radiating unit 161 may radiate a laser L toward the processing surface PS of the target T while being moved along the processing path PR. The laser moving unit 162 may move the laser radiating unit 161 in a horizontal direction (e.g., the X-axis and/or Y-axis direction) with respect to the base B along the processing path PR. The laser radiating unit 161 may radiate the laser L toward the processing surface PS of the target T while being moved by the laser moving unit 162. In such an embodiment, the processing surface PS of the target T may be processed while the laser radiating unit 161 is moved in a state in which the target T is fixed. Accordingly, processing may be precisely and efficiently performed regardless of the weight and size of the target T. In addition, because the target T is fixed in a processing operation, the size of the chamber 11 may be reduced. Accordingly, the size of the apparatus 1 for manufacturing a display apparatus may be reduced.

The pressure adjusting unit 15 may operate in any one of states illustrated in FIGS. 2A to 2E. In an embodiment, for example, the pressure adjusting unit 15 may operate when the stage unit 12 is at the processing position PP as shown in FIG. 2C. That is, after the operation of the target moving unit 13 is completed, the loading area LA may be vacuumed. Accordingly, the target moving unit 13 may not be affected by the pressure of the loading area LA while operating.

Because the optical unit 16 is arranged outside the chamber 11 instead of being arranged in the loading area LA in which the pressure thereof is adjusted, processing may be precisely and efficiently performed on the processing surface PS of the target T. In an embodiment, for example, the optical unit 16 may be operable regardless of the pressure of the loading area LA. Accordingly, the optical unit 16 may not be provided with separate vacuum equipment for operating the optical unit 16 in a vacuum state. In addition, cooling of the optical unit 16, which is not affected by the pressure of the pressure of the loading area LA, may be easy, and inspection and repair of the optical unit 16 may be easy. Because the laser moving unit 162 is not affected by the pressure of the loading area LA, the laser moving unit 162 may include an air-bearing. Accordingly, the laser moving unit 162 move the laser L more precisely.

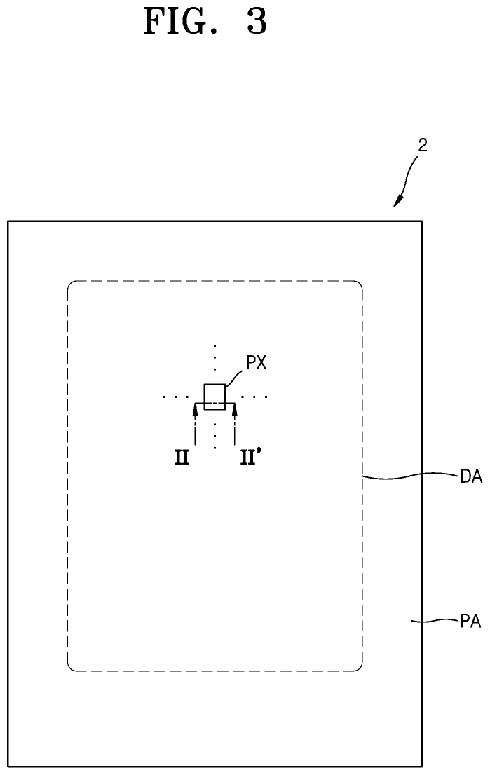

FIG. 3 is a plan view schematically illustrating a display apparatus 2 manufactured by a method of manufacturing a display apparatus, according to an embodiment.

Referring to FIG. 3, the display apparatus 2 manufactured according to an embodiment may include a display area DA and a peripheral area PA outside the display area DA. The display apparatus 2 may provide an image through an array of a plurality of pixels PX, which are two-dimensionally arranged in the display area DA.

The peripheral area PA is an area, which may entirely or partially surround the display area DA and does not provide an image. A driver configured to provide electrical signals or power to a pixel circuit corresponding to each of the plurality of pixels PX or the like may be arranged in the peripheral area PA. A pad, which is an area to which an electronic device or a printed circuit board may be electrically connected, may be arranged in the peripheral area PA.

Hereinafter, for convenience of description, embodiments where the display apparatus 2 includes an organic light-emitting diode (OLED) as a light-emitting element thereof will be described detail, but the display apparatus 2 is not limited thereto. In an alternative embodiment, the display apparatus 2 may be a light-emitting display apparatus including an inorganic light-emitting diode, that is, an inorganic light-emitting display apparatus. The inorganic light-emitting diode may include a PN junction diode including materials based on inorganic semiconductors. When a voltage is applied to the PN junction diode in a forward direction, holes and electrons may be injected, and energy generated by recombination of the holes and electrons may be converted into light energy to emit a certain color of light. The inorganic light-emitting diode described above may have a width of several micrometers to several hundreds of micrometers, and in some embodiments, the inorganic light-emitting diode may be referred to as a micro light-emitting diode (LED). In an alternative embodiment, the display apparatus 2 may be a quantum dot light-emitting display apparatus.

The display apparatus 2 may be a portable electronic device, such as a mobile phone, a smartphone, a table personal computer (PC), a mobile communication terminal, an electronic notebook, an electronic book, a portable multimedia player (PMP), a navigation device, an ultra mobile PC (UMPC), or the like, and may also be used as a display screen of various products, such as a television, a laptop computer, a monitor, an advertisement board, an Internet of things (IoT) device, or the like. In addition, the display apparatus 2 according to an embodiment may be used as a wearable device, such as a smart watch, a watch phone, a glasses-type display, and a head-mounted display (HMD). In addition, the display apparatus 2 according to an embodiment may be used as a dashboard of a vehicle, a center fascia of a vehicle or a center information display (CID) disposed on a dashboard, a room mirror display replacing a side mirror of a vehicle, and a display screen disposed on a back surface of a front seat as entertainment for a back seat of a vehicle.

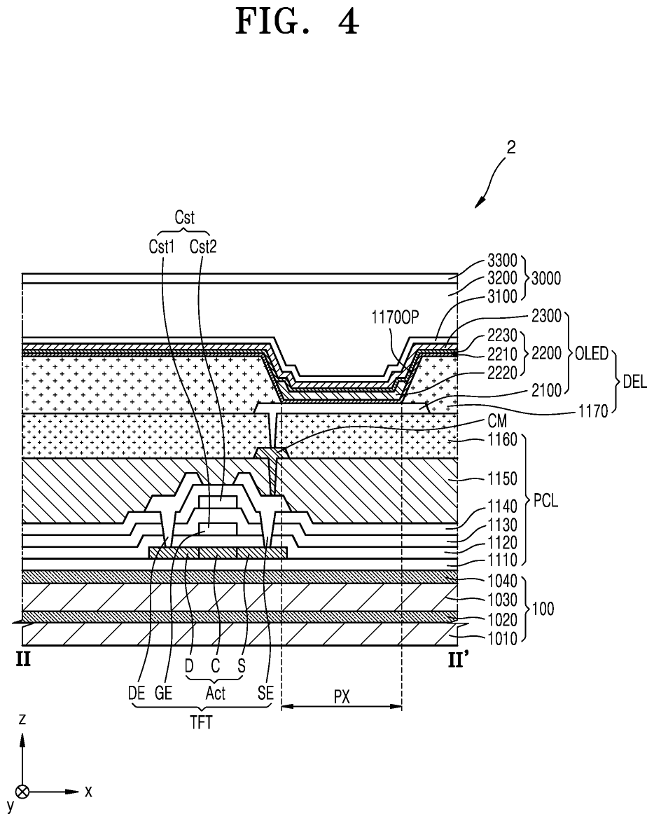

FIG. 4 is a cross-sectional view schematically illustrating the display apparatus 2 manufactured by a method of manufacturing a display apparatus according to an embodiment, taken along line II-II′ of FIG. 3.

Referring to FIG. 4, an embodiment of the display apparatus 2 may include a substrate 1000, a pixel circuit layer PCL, a display element layer DEL, a stacked structure of an encapsulation layer 3000.

The substrate 1000 may have a multi-layered structure including a base layer and an inorganic layer, and the base layer includes a polymer resin. In an embodiment, for example, the substrate 1000 may include a base layer including a polymer resin, and a barrier layer of an inorganic insulating layer. In an embodiment, for example, the substrate 1000 may include a first base layer 1010, a first barrier layer 1020, a second base layer 1030, and a second barrier layer 1040, which are sequentially stacked one on another. The first base layer 1010 and the second base layer 1030 may each include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC), or/and cellulose acetate propionate (CAP), or the like. The first barrier layer 1020 and the second barrier layer 1040 may each include an inorganic insulating material, such as silicon oxide, silicon nitride, and/or silicon oxynitride. The substrate 1000 may be flexible.

The pixel circuit layer PCL may be disposed on the substrate 1000. FIG. 4 illustrates an embodiment where the pixel circuit layer PCL includes a thin-film transistor TFT, and a buffer layer 1110, a first gate insulating layer 1120, a second gate insulating layer 1130, an interlayer insulating layer 1140, a first planarization insulating layer 1150, and a second planarization insulating layer 1160, and the buffer layer 1110, the first gate insulating layer 1120, the second gate insulating layer 1130, the interlayer insulating layer 1140, the first planarization insulating layer 1150, and the second planarization insulating layer 1160 are disposed below or/and above components of the thin-film transistor TFT.

The buffer layer 1110 may reduce or block penetration of foreign materials, moisture, or external air from a lower portion of the substrate 1000, and may provide a flat surface on the substrate 1000. The buffer layer 1110 may include an inorganic insulating material, such as silicon oxide, silicon oxynitride, and silicon nitride, and may include a single layer or a multi-layer, each layer including at least one selected from the above-stated materials.

The thin-film transistor TFT disposed on the buffer layer 1110 may include a semiconductor layer Act, and the semiconductor layer Act may include polysilicon. Alternatively, the semiconductor layer Act may include an amorphous silicon, an oxide semiconductor, an organic semiconductor, or the like. The semiconductor layer Act may include a channel area C, a drain area D, and a source area S, where the drain area D and the source area S are respectively arranged on both sides of the channel area C. A gate electrode GE of the thin-film transistor TF may overlap the channel area C.

The gate electrode GE may include a low-resistance metal material. The gate electrode GE may include a conductive material including molybdenum (Mo), aluminum (AI), copper (Cu), titanium (Ti), or the like, and may be a multi-layer or a single layer, each layer including at least one selected from the above-stated materials.

The first gate insulating layer 1120 between the semiconductor layer Act and the gate electrode GE may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may be zinc oxide (ZnO) and/or zinc peroxide (ZnO₂).

The second gate insulating layer 1130 may cover the gate electrode GE. Similar to the first gate insulating layer 1120, the second gate insulating layer 1130 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may be zinc oxide (ZnO) and/or zinc peroxide (ZnO₂).

An upper electrode Cst2 of a storage capacitor Cst may be disposed on the second gate insulating layer 1130. The upper electrode Cst2 may overlap the gate electrode GE therebelow. In such an embodiment, the gate electrode GE and the upper electrode Cst2, which overlap each other with the second gate insulating layer 1130 therebetween, may form the storage capacitor Cst. That is, the gate electrode GE may function as a lower electrode Cst1 of the storage capacitor Cst.

In such an embodiment, the storage capacitor Cst and the thin-film transistor TFT may overlap each other. In some embodiments, the storage capacitor Cst may not overlap the thin-film transistor TFT.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be a single layer or a multi-layer, each layer including at least one selected from the materials stated above.

The interlayer insulating layer 1140 may cover the upper electrode Cst2. The interlayer insulating layer 1140 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may be zinc oxide (ZnO) and/or zinc peroxide (ZnO₂). The interlayer insulating layer 1140 may include a single layer or a multi-layer, each layer including at least one selected from the inorganic insulating materials stated above.

Each of a drain electrode DE and a source electrode SE may be positioned on the interlayer insulating layer 1140. The drain electrode DE and the source electrode SE may respectively be connected to the drain electrode DE and the source electrode SE through contact holes defined in insulating layers below the drain electrode DE and the source electrode SE. The drain electrode DE and the source electrode SE may each include a material having high conductivity. The drain electrode DE and the source electrode SE may include a conductive material including Mo, Al, Cu, Ti, or the like, and may include a multi-layer or a single layer, each layer including at least one selected from the above materials. In an embodiment, the drain electrode DE and the source electrode SE may each have a multi-layered structure of Ti/AI/Ti.

The first planarization insulating layer 1150 may cover the drain electrode DE and the source electrode SE. The first planarization insulating layer 1150 may include a general commercial polymer, such as poly(methyl methacrylate) (PMMA) or polystyrene (PS), a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, or a mixture thereof.

The second planarization insulating layer 1160 may be disposed on the first planarization insulating layer 1150. The second planarization insulating layer 1160 may include the same material as that of the first planarization insulating layer 1150, and may include a general commercial polymer, such as PMMA or PS, a polymer derivative having a phenol group, or an organic insulating material, such as an acrylic polymer, an imide polymer, an aryl ether polymer, an amide polymer, a fluorine polymer, a p-xylene polymer, a vinyl alcohol polymer, or a mixture thereof.

The display element layer DEL may be disposed on the pixel circuit layer PCL having the structure described above. The display element layer DEL may include an organic light-emitting diode OLED as a display element (that is, a light-emitting element), and the organic light-emitting diode OLED may include a stacked structure of a pixel electrode 2100, an intermediate layer 2200, and a common electrode 2300. The organic light-emitting diode OLED may emit, for example, red, green, or blue light, or may emit red, green, blue, or white light. The organic light-emitting diode OLED may emit light through an emission area, and define the emission area as a pixel PX.

The pixel electrode 2100 of the organic light-emitting diode OLED may be electrically connected to the thin-film transistor TFT through contact holes defined in the second planarization insulating layer 1160 and the first planarization insulating layer 1150 and a contact metal CM disposed on the first planarization insulating layer 1150.

In an embodiment, the pixel electrode 2100 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an alternative embodiment, the pixel electrode 2100 may include a reflective film including Ag, Mg, Al, Pt, Pd, Au, Ni, Nd, Ir, Cr, or a compound thereof. In an alternative embodiment, the pixel electrode 2100 may further include a film including ITO, IZO, ZnO, or In₂O₃ above/below the reflective film.

A pixel defining layer 1170 with an opening 1170P defined therethrough to expose a central portion of the pixel electrode 2100 is disposed on the pixel electrode 2100. The pixel defining layer 1170 may include an organic insulating material and/or an inorganic insulating material. The opening 1170P may define an emission area of light emitted from the organic light-emitting diode OLED. In an embodiment, for example, the size/width of the opening 1170P may correspond to the size/width of the emission area. Accordingly, the size and/or width of the pixel PX may depend on the size and/or width of the opening 1170P of the pixel defining layer 1170 corresponding to the pixel PX.

The intermediate layer 2200 may include an emission layer 2220 formed to correspond to the pixel electrode 2100. The emission layer 2220 may include a polymer organic material or a low-molecular-weight organic material, which emits light of a certain color. Alternatively, the emission layer 2220 may include an inorganic light-emitting material or a quantum dot.

As an embodiment, the intermediate layer 2200 may include a first functional layer 2210 and a second functional layer 2230 respectively disposed below and on the emission layer 2220. The first functional layer 2210 may include a hole transport layer (HTL), or an HTL and a hole injection layer (HIL). The second functional layer 2230 is a component disposed on the emission layer 2220, and may include an electron transport layer ETL and/or an electron injection layer (EIL). Similar to the common electrode 2300 to be described below, the first functional layer 2210 and/or the second functional layer 2230 may be a common layer entirely covering the substrate 1000.

The common electrode 2300 may be disposed above the pixel electrode 2100 and overlap the pixel electrode 2100. The common electrode 2300 may include a conductive material having a low work function. In an embodiment, for example, the common electrode 2300 may include a (semi)transparent layer including Ag, Mg, Al, Pt, Pd, Au, Ni, Nd, Ir, Cr, lithium (Li), Ca, an alloy thereof, or the like. Alternatively, the common electrode 2300 may further include a layer, such as ITO, IZO, ZnO, or In₂O₃, above the (semi)transparent layer including the materials stated above. The common electrode 2300 may be integrally formed as a single unitary part to entirely cover the substrate 1000.

The encapsulation layer 3000 may be disposed on the display element layer DEL and cover the display element layer DEL. The encapsulation layer 3000 may include at least one inorganic encapsulation layer and at least one organic encapsulation layer. In an embodiment, as shown in FIG. 12, the encapsulation layer 3000 includes a first inorganic encapsulation layer 3100, an organic encapsulation layer 3200, and a second inorganic encapsulation layer 3300, which are sequentially stacked one on another.

The first inorganic encapsulation layer 3100 and the second inorganic encapsulation layer 3300 may each include at least one inorganic material selected from aluminum oxide, titanium oxide, tantalum oxide, hafnium oxide, zinc oxide, silicon oxide, silicon nitride, and silicon oxynitride. The organic encapsulation layer 3200 may include a polymer-based material. The polymer-based material may include an acrylic resin, an epoxy resin, polyimide, polyethylene, or the like. In an embodiment, the organic encapsulation layer 3200 may include acrylate. The organic encapsulation layer 3200 may be formed by curing a monomer or coating a polymer. The organic encapsulation layer 3200 may have transparency.

Although not shown in FIG. 4, a touch sensor layer may be disposed on the encapsulation layer 3000, and an optical functional layer may be disposed on the touch sensor layer. The touch sensor layer may obtain coordinate information according to an external input, for example, a touch event. The optical functional layer may reduce the reflectance of light (external light) incident from the outside toward the display apparatus, and/or improve color purity of light emitted by the display apparatus. As an embodiment, the optical functional layer may include a retarder and/or a polarizer. The retarder may be a film type or a liquid-crystal coating type, and may include a λ/2 retarder and/or a λ/4 retarder. The polarizer may also be a film type or a liquid-crystal coating type. The film-type polarizer may include a stretch-type synthetic resin film, and the liquid-crystal-coating-type polarizer may include liquid crystals in a certain arrangement. The retarder and the polarizer may further include a protective film.

An adhesive member may be arranged between the touch sensor layer and the optical functional layer. As the adhesive member, a general adhesive member known in the related art may be employed without limitation. The adhesive member may be a pressure sensitive adhesive (PSA).

The fixing surface FS of the target T described above with respect to FIGS. 1 to 2E may be the lower surface of the substrate 1000. In addition, the processing surface PS of the target T may be an upper surface of at least one selected from several layers disposed on the substrate 1000.

In an embodiment, for example, the processing surface PS of the target T may be an upper surface of the first planarization insulating layer 1150. Accordingly, the laser radiating unit 161 may radiate the laser L to the upper surface of the first planarization insulating layer 1150. A contact hole may be formed in the first planarization insulating layer 1150 by the laser L radiated by the laser radiating unit 161 to allow the contact metal CM to pass therethrough.

In an embodiment, for example, the processing surface PS of the target T may be the upper surface of the second planarization insulating layer 1160. Accordingly, the laser radiating unit 161 may radiate the laser L to the upper surface of the second planarization insulating layer 1160. A contact hole may be formed in the second planarization insulating layer 1160 by the laser L radiated by the laser radiating unit 161 to allow the pixel electrode 2100 to pass therethrough.

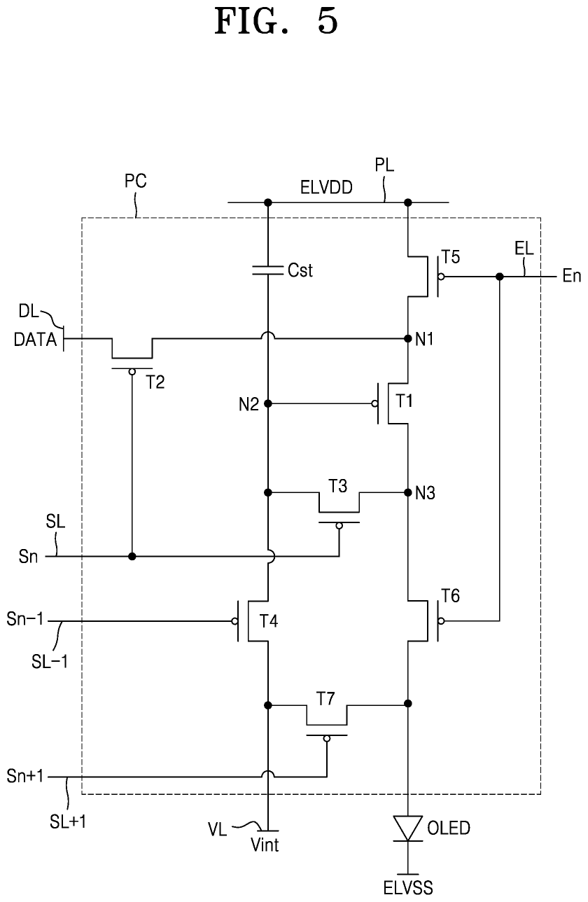

FIG. 5 is an equivalent circuit diagram of a pixel according to an embodiment.

Referring to FIG. 5, an embodiment of a pixel circuit PC may include first to seventh transistors T1 to T7, and according to a transistor type (p-type or n-type) and/or an operating condition, a first terminal of each of the first to seventh transistors T1 to T7 may be a source terminal or a drain terminal, and a second terminal thereof may be a terminal different from the first terminal. In an embodiment, for example, the first terminal is a source terminal, and the second terminal may be a drain terminal.

The pixel circuit PC may be connected to a first scan line SL configured to transmit a first scan signal Sn, a second scan line SL−1 configured to transmit a second scan signal Sn−1, a third scan line SL+1 configured to transmit a third scan signal Sn+1, an emission control line EL configured to transmit an emission control signal En, a data line DL configured to transmit a data signal DATA, a driving voltage line PL configured to transmit a driving voltage ELVDD, and an initialization voltage line VL configured to transmit an initialization voltage Vint.

The first transistor T1 includes a gate terminal connected to a second node N2, a first terminal connected to a first node N1, and a second terminal connected to a third node N3. The first transistor T1 functions as a driving transistor and receives the data signal DATA based on a switching operation of the second transistor T2 to supply a driving current to a light-emitting element. The light-emitting element may be an organic light-emitting diode OLED.

The second transistor T2 (switching transistor) includes a gate terminal connected to the first scan line SL, a first terminal connected to the data line DL, and a second terminal connected to the first node N1 (or the first terminal of the first transistor T1). The second transistor T2 may be turned on in response to the first scan signal Sn received through the first scan line SL and may perform a switching operation of providing the data signal DATA provided to the data line DL to the first node N1.

The third transistor T3 (compensation transistor) includes a gate terminal connected to the first scan line SL, a first terminal connected to the second node N2 (or the gate terminal of the first transistor T1), and a second terminal connected to the third node N3 (the second terminal of the first transistor T1). The third transistor T3 may be turned on in response to the first scan signal Sn received via the first scan line SL to diode-connect the first transistor T1. The third transistor T3 may have a structure in which two or more transistors are connected in series.

The fourth transistor T4 (first initialization transistor) includes a gate terminal connected to the second scan line SL−1, a first terminal connected to the initialization voltage line VL, and a second terminal connected to the second node N2. The fourth transistor T4 may be turned on according to the second scan signal Sn−1 received through the second scan line SL−1 and configured to transmit the initialization voltage Vint to the gate terminal of the first transistor T1 to initialize a gate voltage of the first transistor T1. The fourth transistor T4 may have a structure in which two or more transistors are connected in series.

The fifth transistor T5 (first emission-control transistor) includes a gate terminal connected to the emission control line EL, a first terminal connected to the driving voltage line PL, and a second terminal connected to the first node N1. The sixth transistor T6 (second emission-control transistor) includes a gate terminal connected to the emission control line EL, a first terminal connected to the third node N3, and a second terminal connected to a pixel electrode of the organic light-emitting diode OLED. The fifth transistor T5 and the sixth transistor T6 are simultaneously turned on in response to the emission control signal En received through the emission control line EL, and thus, a current flows to the organic light-emitting diode OLED.

The seventh transistor T7 (second initialization transistor) includes a gate terminal connected to the third scan line SL+1, a first terminal connected to the second terminal of the sixth transistor T6 and the pixel electrode of the organic light-emitting diode OLED, and a second terminal connected to the initialization voltage line VL. The seventh transistor T7 may be turned on in response to the third scan signal Sn+1 received through the third scan line SL+1 and configured to transmit the initialization voltage Vint to the pixel electrode of the organic light-emitting diode OLED to initialize a voltage of the pixel electrode of the organic light-emitting diode OLED. The seventh transistor T7 may be omitted.

A capacitor Cst includes a first electrode connected to the second node N2 and a second electrode connected to the driving voltage line PL.

The organic light-emitting diode OLED may include the pixel electrode and an opposite electrode facing the pixel electrode, and the opposite electrode may receive a common voltage ELVSS. The organic light-emitting diode OLED may receive a driving current from the first transistor T1 and emit light in a certain color to display an image. The opposite electrode may be provided in common to a plurality of pixels, that is, the opposite electrodes of the pixels are integrally formed as a single unitary unit.

FIG. 5 illustrates an embodiment in which the fourth transistor T4 and the seventh transistor T7 are respectively connected to the second scan line SL−1 and the third scan line SL+1, but the disclosure is not limited thereto. In an alternative embodiment, the fourth transistor T4 and the seventh transistor T7 may both be connected to the second scan line SL−1 to be driven based on the second scan signal Sn−1.

According to embodiments, the size of an apparatus for manufacturing a display apparatus may be reduced, and processing may be precisely and efficiently performed on a target in an operation of processing the target by radiating a laser.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display apparatus, the apparatus comprising
a chamber in which a loading area is defined;
a stage unit disposed in the loading area, wherein the stage unit fixes a fixing surface of a target; and
an optical unit disposed outside the chamber, wherein the optical unit processes a processing surface of the target,
wherein the optical unit comprises:
a laser radiating unit which radiates a laser toward the processing surface of the target; and
a laser moving unit which moves the laser radiating unit along a processing path in a plan view.

2. The apparatus of claim 1, further comprising:
a target moving unit disposed in the loading area, wherein the target moving unit moves the stage unit, to which the target is fixed, to a processing position.

3. The apparatus of claim 2, wherein the target moving unit comprises a target rotationally-moving unit which rotates the stage unit around a first axis.

4. The apparatus of claim 3, wherein the stage unit fixes the fixing surface of the target in a state in which the processing surface of the target faces a direction in which the laser is directed.

5. The apparatus of claim 4, wherein the target rotationally-moving unit rotates the stage unit in a way such that the processing surface of the target fixed to the stage unit faces a direction opposite to the direction in which the laser is directed.

6. The apparatus of claim 2, wherein the target moving unit further comprises a target vertically-moving unit which moves the stage unit in a direction opposite to a direction in which the laser is directed.

7. The apparatus of claim 1, further comprising:
a pressure adjusting unit which adjusts a pressure of the loading area.

8. The apparatus of claim 1, further comprising:
a window disposed on one side of the chamber, which is between the laser radiating unit and the stage unit,
wherein the window comprises a transparent material to allow the laser to pass therethrough.

9. The apparatus of claim 1, wherein the optical unit further comprises a laser aligning unit which aligns the laser radiating unit to an alignment position.

10. The apparatus of claim 1, wherein the laser moving unit comprises an air-bearing.

11. A method of manufacturing a display apparatus, the method comprising:
performing a stage unit arrangement operation by arranging a stage unit to a loading area inside a chamber;
performing a target fixing operation by fixing a fixing surface of a target to the stage unit; and
performing a processing operation by processing a processing surface of the target,
wherein the performing the processing operation comprises:
performing a laser radiating operation by radiating a laser from a laser radiating unit disposed outside the chamber toward the processing surface of the target; and
performing a laser moving operation by moving the laser radiating unit along a processing path in a plan view.

12. The method of claim 11, further comprising:
performing a target moving operation by moving the stage unit, to which the target is fixed, to a processing position.

13. The method of claim 12, wherein the performing the target moving operation comprises performing a target rotationally-moving operation by rotating the stage unit around a first axis.

14. The method of claim 13, wherein the performing the target fixing operation comprises fixing the fixing surface of the target to the stage unit in a state in which the processing surface of the target faces a direction in which the laser is directed.

15. The method of claim 14, wherein the performing the target rotationally-moving operation comprises rotating the stage unit in a way such that the processing surface of the target fixed to the stage unit faces a direction opposite to the direction in which the laser is directed.

16. The method of claim 13, wherein the performing the target moving operation further comprises performing a target vertically-moving operation by moving the stage unit in a direction opposite to a direction in which the laser is directed.

17. The method of claim 11, further comprising:
performing a pressure adjusting operation by adjusting a pressure of the loading area.

18. The method of claim 11, wherein the performing the laser radiating operation comprises radiating the laser from the laser radiating unit in a way such that the laser reaches the processing surface of the target through a window disposed on one side of the chamber.

19. The method of claim 11, wherein the performing the processing operation further comprises performing a laser aligning operation by aligning the laser radiating unit to an alignment position.

20. The method of claim 11, wherein the performing the laser moving operation comprises moving the laser radiating unit along an air-bearing.
